(19) United States
(12) Patent Application Publication
(10) Pub. No.: US 2026/0247919 A1
(43) Pub. Date: Aug. 20, 2026

(54) SYSTEM FOR FIXING SEMICONDUCTOR WAFER TO ELECTROSTATIC CHUCK AND METHOD FOR FIXING SEMICONDUCTOR WAFER TO ELECTROSTATIC CHUCK USING SAME

(71) Applicant: YOULCHON CHEMICAL CO., LTD., Seoul (KR)

(72) Inventors: Ji Moon LEE, Ansan-si (KR); Sang Gil DOH, Ansan-si (KR); Gyeong Seok YU, Ansan-si (KR); Kyu Wan LEE, Ansan-si (KR); Chang Woo LEE, Ansan-si (KR); Young Hun JANG, Ansan-si (KR); Han Bin CHO, Ansan-si (KR); Tae Yong HA, Ansan-si (KR); Kyoung Mi SONG, Ansan-si (KR)

(73) Assignee: YOULCHON CHEMICAL CO., LTD., Seoul (KR)

(21) Appl. No.: 19/161,860

(22) PCT Filed: Nov. 20, 2024
(86) PCT No.: PCT/KR2024/018403

§ 371 Date: Sep. 3, 2025

(30) Foreign Application Priority Data
Dec. 11, 2023 (KR) 10-2023-0178854
Jul. 31, 2024 (KR) 10-2024-0101920
Oct. 30, 2024 (KR) 10-2024-0151354
Nov. 8, 2024 (KR) 10-2024-0157857

(51) Int. Cl. H10P 72/70; H10P 72/72

(52) U.S. Cl. CPC H10P 72/7402; H10P 72/72; H10P 72/7412

(57) ABSTRACT

A system for fixing a semiconductor wafer to an electrostatic chuck according to an embodiment of the present disclosure includes an electrostatic chuck, a semiconductor adhesive film including a base layer, a conductive layer formed on the base layer, and an adhesive layer formed on the conductive layer, in which the semiconductor adhesive film is fixed to the electrostatic chuck so that the base layer faces the electrostatic chuck, and a semiconductor wafer adhering to the adhesive layer.

According to the present disclosure, the system for fixing the semiconductor wafer to the electrostatic chuck and the method for fixing the semiconductor wafer to the electrostatic chuck enable the semiconductor wafer to be stably fixed to and separated from the electrostatic chuck by adhering the semiconductor adhesive film to the semiconductor wafer.

### TECHNICAL FIELD

The present disclosure relates to a system for fixing a semiconductor wafer to an electrostatic chuck and a method for fixing a semiconductor wafer to an electrostatic chuck using the same, and more particularly, to a system for fixing a semiconductor wafer to an electrostatic chuck capable of stably fixing and stably separating a semiconductor wafer to and from an electrostatic chuck (ESC) and a method for fixing a semiconductor wafer to an electrostatic chuck using the same.

### BACKGROUND ART

Recently, there has been an increasing demand for thinning and miniaturizing semiconductor devices and their packages. Accordingly, as semiconductor wafers become thinner, electrostatic chucks (ESCs) are used to effectively fix the semiconductor wafers. The ESC is a device used to fix the wafer in a semiconductor manufacturing process, and fixes the wafer using electrical force, and minimizes damage due to contact and provides uniform fixing force, unlike conventional physical clamps or vacuum suction methods.

In order to fix the semiconductor wafer to the ESC, a semiconductor adhesive film may adhere to the wafer. At this time, in order to fix the wafer to the ESC through an electrical force, the semiconductor adhesive film needs to have suitable electrical properties, and simultaneously to minimize the occurrence of residues or bubbles that may occur when adhering to the semiconductor wafer. In addition, when a voltage is applied to the ESC, the semiconductor wafer needs to be stably fixed to the ESC, and when no voltage is applied to the ESC, the semiconductor adhesive film needs to be designed so that the semiconductor wafer may be separated from the ESC.

### PRIOR ARTS

### Patent Documents

(Patent Document 1) KR 10-2208071 B1

### DISCLOSURE

### Technical Problem

In order to solve the above-described problems, an object of the present disclosure is to provide a system for fixing a semiconductor wafer to an electrostatic chuck and a method for fixing a semiconductor wafer to an electrostatic chuck using the same, capable of stably fixing or separating the semiconductor wafer to or from the electrostatic chuck.

Another object of the present disclosure is to provide a system for fixing a semiconductor wafer to an electrostatic chuck and a method for fixing a semiconductor wafer to an electrostatic chuck using the same, capable of minimizing the occurrence of residues or bubbles that may occur when an semiconductor adhesive film adheres to the semiconductor wafer in the system for fixing the semiconductor wafer to the electrostatic chuck.

### Technical Solution

According to an embodiment of the present disclosure, a system for fixing a semiconductor wafer to an electrostatic chuck includes an electrostatic chuck, a semiconductor adhesive film including a base layer, a conductive layer formed on the base layer, and an adhesive layer formed on the conductive layer, in which semiconductor adhesive film is fixed to the electrostatic chuck so that the base layer faces the electrostatic chuck, and a semiconductor wafer adhering to the adhesive layer.

In the system for fixing the semiconductor wafer to the electrostatic chuck according to an embodiment of the present disclosure, the adhesive layer of the semiconductor adhesive film may adhere to the coating layer formed on the semiconductor wafer.

In the system for fixing the semiconductor wafer to the electrostatic chuck according to an embodiment of the present disclosure, the semiconductor wafer may be fixed to the electrostatic chuck when a voltage is applied to the electrostatic chuck, and the semiconductor wafer may be separated from the electrostatic chuck when no voltage is applied to the electrostatic chuck.

In the system for fixing the semiconductor wafer to the electrostatic chuck according to an embodiment of the present disclosure, the semiconductor adhesive film may include a release film layer formed on the adhesive layer, and the semiconductor wafer may adhere to the adhesive layer after the release film layer is peeled from the adhesive layer.

In the system for fixing the semiconductor wafer to the electrostatic chuck according to an embodiment of the present disclosure, while the semiconductor adhesive film is fixed to the electrostatic chuck before the release film layer is removed, a force by which the electrostatic chuck horizontally fixes the semiconductor adhesive film may be formed to be 200 gf/150 mm or more when a voltage is applied to the electrostatic chuck, and the force by which the electrostatic chuck horizontally fixes the semiconductor adhesive film may be formed to be 1 gf/150 mm or less when no voltage is applied to the electrostatic chuck.

In the system for fixing the semiconductor wafer to the electrostatic chuck according to an embodiment of the present disclosure, the magnitude of a force of peeling the release film layer from the adhesive layer in the semiconductor adhesive film may be formed to be 0.8 to 1.1 gf/25 mm.

In the system for fixing the semiconductor wafer to the electrostatic chuck according to an embodiment of the present disclosure, an adhesive force formed between the coating layer and the adhesive layer may be 0.8 to 2.5 gf/25 mm.

In the system for fixing the semiconductor wafer to the electrostatic chuck according to an embodiment of the present disclosure, the adhesive force formed between the coating layer and the adhesive layer may be maintained even at 10° C. to 110° C.

In the system for fixing the semiconductor wafer to the electrostatic chuck according to an embodiment of the present disclosure, the semiconductor adhesive film while the release film layer is removed may have a Young's modulus value of 3500 to 4300 N/mm².

In the system for fixing the semiconductor wafer to the electrostatic chuck according to an embodiment of the present disclosure, the adhesive layer may include a silicone-based compound.

In the system for fixing the semiconductor wafer to the electrostatic chuck according to an embodiment of the present disclosure, the coating layer may be formed of an organic coating agent.

According to an embodiment of the present disclosure, a method for fixing a semiconductor wafer to an electrostatic chuck by using a semiconductor adhesive film in which a base layer, a conductive layer, an adhesive layer, and a release film layer are laminated in sequence, the method may include a semiconductor adhesive film fixing step of fixing the semiconductor adhesive film to the electrostatic chuck so that the base layer faces the electrostatic chuck after a voltage is applied to the electrostatic chuck; a release film layer peeling step of peeling the release film layer from the adhesive layer of the semiconductor adhesive film; and a semiconductor wafer adhering step of adhering the semiconductor wafer to the adhesive layer.

The method for fixing the semiconductor wafer to the electrostatic chuck according to an embodiment of the present disclosure may include an electrostatic chuck separating step of separating the semiconductor wafer and the semiconductor adhesive film together from the electrostatic chuck after the applied voltage to the electrostatic chuck is turned off; and a semiconductor wafer peeling step of separating the semiconductor wafer from the adhesive layer.

In the method for fixing the semiconductor wafer to the electrostatic chuck according to an embodiment of the present disclosure, in the semiconductor wafer adhering step, the coating layer formed on the semiconductor wafer and the adhesive layer may adhere to each other.

In the method for fixing the semiconductor wafer to the electrostatic chuck according to an embodiment of the present disclosure, in the semiconductor wafer peeling step, the coating layer and the adhesive layer may be separated from each other.

In the method for fixing the semiconductor wafer to the electrostatic chuck according to an embodiment of the present disclosure, in the semiconductor adhesive film fixing step, a force by which the electrostatic chuck horizontally fixes the semiconductor adhesive film when a voltage is applied to the electrostatic chuck may be formed to be 200 gf/150 mm or more.

In the method for fixing the semiconductor wafer to the electrostatic chuck according to an embodiment of the present disclosure, in the electrostatic chuck separating step, the force by which the electrostatic chuck horizontally fixes the semiconductor adhesive film when no voltage is applied to the electrostatic chuck may be formed to be 1 gf/150 mm or less.

In the method for fixing the semiconductor wafer to the electrostatic chuck according to an embodiment of the present disclosure, in the semiconductor wafer peeling step, the magnitude of a force of peeling the release film layer from the adhesive layer in the semiconductor adhesive film may be formed to be 0.8 to 1.1 gf/25 mm.

In the method for fixing the semiconductor wafer to the electrostatic chuck according to an embodiment of the present disclosure, in the semiconductor wafer peeling step, the adhesive force formed between the coating layer and the adhesive layer may be formed to be 0.8 to 2.5 gf/25 mm.

In the method for fixing the semiconductor wafer to the electrostatic chuck according to an embodiment of the present disclosure, in the semiconductor wafer peeling step, the adhesive force formed between the coating layer and the adhesive layer may be maintained even at 10° C. to 110° C.

In the method for fixing the semiconductor wafer to the electrostatic chuck according to an embodiment of the present disclosure, after the release film layer peeling step, the semiconductor adhesive film may have a Young's modulus value of 3500 to 4300 N/mm².

In the method for fixing the semiconductor wafer to the electrostatic chuck according to an embodiment of the present disclosure, the adhesive layer may include a silicone-based compound.

In the method for fixing the semiconductor wafer to the electrostatic chuck according to an embodiment of the present disclosure, the coating layer may be formed of an organic coating agent.

### Advantageous Effects

According to the present disclosure, the system for fixing the semiconductor wafer to the electrostatic chuck and the method for fixing the semiconductor wafer to the electrostatic chuck enable the semiconductor wafer to be stably fixed to and separated from the electrostatic chuck by adhering the semiconductor adhesive film to the semiconductor wafer.

In addition, in the system for fixing the semiconductor wafer to the electrostatic chuck and the method for fixing the semiconductor wafer to the electrostatic chuck, it is possible to establish conditions such as specific force, adhesive force, and Young's modulus for fixing the semiconductor wafer to the electrostatic chuck, and thereby to minimize the occurrence of residues or bubbles that may occur when the semiconductor adhesive film adheres to the semiconductor wafer in the system for fixing the semiconductor wafer to the electrostatic chuck.

### DESCRIPTION OF DRAWINGS

FIG. 1 is a schematic diagram of a system for fixing a semiconductor wafer to an electrostatic chuck according to an embodiment of the present disclosure;

FIGS. 2 to 6 are schematic diagrams illustrating a method for fixing a semiconductor wafer to an electrostatic chuck according to an embodiment of the present disclosure; and

FIGS. 7 and 8 are graphs showing Young's modulus values of a semiconductor adhesive film used in a system for fixing a semiconductor wafer to an electrostatic chuck according to an embodiment of the present disclosure.

### BEST MODE

Hereinafter, various embodiments of the present disclosure will be described in detail with reference to the accompanying drawings. The present disclosure is not limited to specific embodiments, and it should be understood to include various modifications, equivalents, and/or alternatives to the embodiments of the present disclosure. In connection with the description of the drawings, similar reference numerals may be used for similar components.

In the present disclosure, expressions such as “have”, “may have”, “include”, or “may include” refer to the presence of the corresponding feature (e.g., components such as numerical values, functions, operations, or components), and do not exclude the presence of additional features.

In the present disclosure, the expression such as “A or B”, “at least one of A or/and B”, or “one or more of A or/and B” may include all possible combinations of items listed together. For example, “A or B”, “at least one of A and B”, or “at least one of A or B” may refer to all cases of (1) including at least one A, (2) including at least one B, or (3) including both at least one A and at least one B.

The expression of “configured to (or set to)” used herein may be changed and used to, for example, “suitable for”, “having the capacity to”, “designed to”, “adapted to”, “made to” or “capable of”, depending on a situation. The term of “configured to (or set to)” does not necessarily mean only “specially designed to”.

The terms used herein are used to illustrate only specific embodiments, and may not be intended to limit the scope of other embodiments. A singular expression may include a plural expression unless the context clearly indicates otherwise. The terms used herein, including technical or scientific terms, may have the same meaning as generally understood by those of ordinary skill in the art described in the present disclosure. The terms defined in a general dictionary among the terms used herein may be interpreted in the same or similar meaning as or to the meaning on the context of the related art, and will not be interpreted as an ideal or excessively formal meaning unless otherwise defined in the present disclosure. In some cases, even the terms defined in the present disclosure can not be interpreted to exclude the embodiments of the present disclosure.

Therefore, the configurations of the embodiments described in the present specification are merely the most preferred embodiment of the present disclosure and are not intended to represent all of the technical ideas of the present disclosure, and thus, it should be understood that there are various equivalents and modifications capable of replacing the configurations at the time of this application.

Throughout the specification, when a certain part “includes” a certain component, unless otherwise specifically stated, it is meant to further include other components rather than excluding other components.

The objects, specific advantages, and new features of the present disclosure will be more clearly understood from the following detailed description and the preferred embodiments taken in conjunction with the accompanying drawings. In the present specification, when reference numerals refer to components of each drawing, it is to be noted that although the same components are illustrated in different drawings, the same components are denoted by the same reference numerals as possible. Further, the terms “one surface”, “other surface”, “first”, “second”, etc. are used to distinguish one component from the other component and the components are not limited by the terms. Hereinafter, in describing the present disclosure, a detailed description of known related art which may make the gist of the present disclosure unnecessarily obscure will be omitted.

Hereinafter, an embodiment of the present disclosure will be described in detail with reference to the accompanying drawings, and the same reference numerals denote the same members.

As used herein, an “electrostatic chuck” as ESC refers to a device that is used to fix a wafer or a film (process tape) in a semiconductor manufacturing process. This device may prevent various problems that may occur during the process by fixing the wafer using static electricity instead of a physical method. The electrostatic chuck has a principle of fixing the wafer using an electrostatic force. This method is a method of generating an electrostatic adsorption force by applying a voltage between the wafer and the electrostatic chuck. The electrostatic chuck is generally designed to have a monopolar or bipolar structure, and each structure may be classified according to the number of electrodes.

As used herein, the “reaction with the electrostatic chuck” refers to that when the semiconductor adhesive film to be described below is positioned close to the electrostatic chuck and a voltage is applied to the electrostatic chuck, mutual static electricity is generated between the semiconductor adhesive film and the electrostatic chuck, so that the electrostatic chuck and the semiconductor adhesive film may be electrostatically chucked by electrostatic attraction.

A system 1 for fixing a semiconductor wafer to an electrostatic chuck according to an embodiment of the present disclosure includes an electrostatic chuck 100, a semiconductor adhesive film 200 including a base layer 210, a conductive layer 220 formed on the base layer 210, and an adhesive layer 230 formed on the conductive layer 220, in which the semiconductor adhesive film is fixed to the electrostatic chuck 100 so that the base layer 210 faces the electrostatic chuck 100, and a semiconductor wafer 300 adhering to the adhesive layer 230.

In the system 1 for fixing the semiconductor wafer to the electrostatic chuck according to an embodiment of the present disclosure, the adhesive layer 230 may include a silicone-based compound.

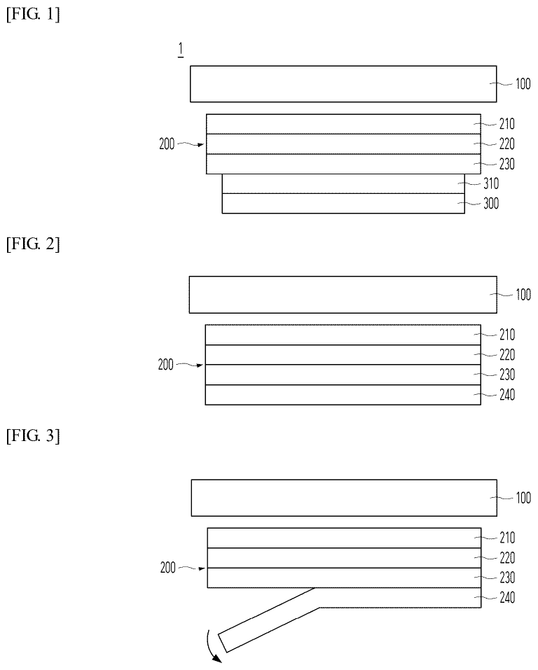

Referring to FIG. 1, the system 1 for fixing the semiconductor wafer to the electrostatic chuck according to an embodiment of the present disclosure is illustrated. The semiconductor wafer 300 adhering to the adhesive layer 230 of the semiconductor adhesive film 200 is fixed to the electrostatic chuck 100. In FIG. 1, the electrostatic chuck 100 is illustrated to be disposed at the upper end, but the arrangement direction of the system 1 may vary, and thus is not limited thereto. When a voltage is applied to the electrostatic chuck 100, the semiconductor adhesive film 200 reacts with the electrostatic chuck 100 and is fixed to the electrostatic chuck 100.

The semiconductor adhesive film 200 is formed in the form in which the base layer 210, the conductive layer 220, and the adhesive layer 230 are laminated in sequence.

The base layer 210 may be selected from the group consisting of polyethylene terephthalate, polyethylene, polyimide, acrylic resin, cycloolefin polymer, mixtures thereof, and copolymers thereof.

The conductive layer 220 may be selected from the group consisting of poly(3,4-ethylenedioxythiophene (PEDOT), poly(3,4-ethylenedioxythiophene) polystyrenesulfonate (PEDOT-PSS), carbon nanotubes (CNT), graphene, indium tin oxide (ITO), silver nanowires, and combinations thereof. The conductive layer 220 constituting the present disclosure is characterized to essentially require transparency in addition to the electrical properties.

In addition, the conductive layer 220 may be formed by crosslinking a mixture of poly(3,4-ethylenedioxythiophene) polystyrenesulfonate and water-dispersed polyurethane with aziridine. When the adhesive layer 230 is formed on the conductive layer 220, the conductive layer 220 may partially be removed by a solvent that dissolves materials constituting the adhesive layer 230. In order to prevent the problem, it is necessary to improve the solvent resistance of the conductive layer 220, but in the present disclosure, the solvent resistance is achieved by crosslinking with aziridine.

In addition, a weight ratio of polyurethane to poly(3,4-ethylenedioxythiophene) polystyrenesulfonate (PEDOT-PSS) in the conductive layer 220 may be 1:9, 1.5:8.5, or 3:7. When the PEDOT-PSS content is less than the above range, the surface resistance, dielectric loss, and dielectric constant conditions that may react with the electrostatic chuck may not be satisfied. On the other hand, when the content exceeds the above range, physical properties may be satisfied, but the polyurethane is small and thus cannot be sufficiently crosslinked with an aziridine crosslinking agent, so that the solvent resistance is not ensured, and it is also not preferable in an economic aspect.

In addition, the weight ratio of the mixture of poly(3,4-ethylenedioxythiophene) polystyrenesulfonate and water-dispersed polyurethane of the conductive layer 220 to aziridine may be 100:8 to 63, 100:10 to 63, or 100:12 to 63. When the weight ratio of aziridine is less than the above range, the aziridine is not sufficiently crosslinked with a carboxyl group of the water-dispersed polyurethane, so that the solvent resistance is not ensured. On the contrary, when the weight ratio exceeds the above range, unreacted aziridine may migrate to the surface according to time and temperature, which is economically undesirable.

In addition, the mixture of poly(3,4-ethylenedioxythiophene) polystyrenesulfonate and water-dispersed polyurethane of the conductive layer 220 may be a solution dissolved in a solvent selected from the group consisting of water, ethanol, methanol, isopropyl alcohol, and a mixture thereof.

In addition, the solution may further include a stabilizer selected from the group consisting of ethylene glycol, sorbitol and a mixture thereof.

In addition, the concentration of the mixture of poly(3,4-ethylenedioxythiophene) polystyrenesulfonate and polyurethane dissolved in the solvent selected from the group consisting of water, ethanol, methanol, isopropyl alcohol, and mixtures thereof may be 0.8 to 1.2 wt % or 0.8 to 0.9 wt %. When the concentration of the solution is less than the above range, particles of PEDOT-PSS may come out to the surface to generate a coating strip on the coating surface. On the contrary, when the concentration exceeds the above range, the solid content is lowered, and when the wet thickness is increased, the surface may not be even due to the fluidity of a coating solution on the coating surface.

The thickness of the conductive layer 220 may be 0.03 to 3 μm. When the thickness of the conductive layer 220 is less than the above range, the surface resistance is high and the dielectric loss is decreased, so that the wafer W to which the semiconductor adhesive film 200 adheres may not be fixed to the electrostatic chuck. In addition, when the thickness of the conductive layer 220 exceeds the above range, the surface resistance is lowered and the dielectric loss is increased, so that the wafer W to which the semiconductor adhesive film 200 adheres may not be fixed to the electrostatic chuck.

In addition, the conductive layer 220 may be gravure-coated on the base layer 210.

In addition, the conductive layer 220 may be dried with hot air at 60 to 100° C. or 20 to 35 Hz for 30 to 90 seconds. When the drying time or the drying temperature is less than the above range, drying is insufficient, and thus curing or volatilization of the solvent is not completely performed, so that electrical properties such as a dielectric constant may be affected.

The adhesive layer 230 may include one or more selected from the group consisting of a rubber-based compound, an acrylic-based compound, a silicone-based compound, and a urethane-based compound, and preferably a silicone-based compound.

The silicone-based compound may be derived from constituent units of organopolysiloxane of the following Chemical Formula 1 or derivative thereof and a hydrogen siloxane copolymer of the following Chemical Formula 2 or derivative thereof.

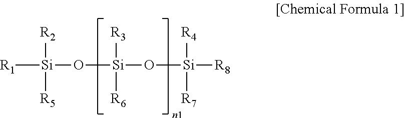

Here, the R₁ and R₈ are each independently any one selected from the group consisting of hydrogen, alkyl and alkenyl, the R₂ to R₇ are either hydrogen or alkyl, and the n1 may be an integer of 5 to 200,000, preferably an integer of 500 to 100,000, and more preferably an integer of 1,000 to 50,000.

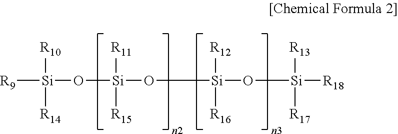

Here, at least one or more of the R₉ to R₁₈ are hydrogen, and the remainder of R₉ to R₁₈ excluding a hydrogen moiety are each independently alkyl, the n2 is an integer of 1 to 200, and the n3 is an integer of 1 to 100.

Preferably, the organopolysiloxane of Chemical Formula 1 or derivative thereof is polydimethylsiloxane containing vinyl groups at both ends, and the molecular weight thereof is 600,000 to 700,000 in weight average molecular weight and 300,000 to 400,000 in number average molecular weight, and the vinyl group content may be 0.02 to 0.2 mmol/g, 0.1 to 0.2 mmol/g, or 0.15 to 0.2 mmol/g. When the vinyl group content is less than the above range, the vinyl group is not sufficiently crosslinked with Si—H and thus may not react with the electrostatic chuck as a dielectric loss value increases. On the contrary, when the vinyl group content exceeds the above range, the crosslinking density with Si—H is increased and thus the vinyl group may not react with the electrostatic chuck as the dielectric loss value decreases.

Preferably, in the hydrogen siloxane copolymer of Chemical Formula 2 or derivative thereof, 1 to 2 hydro groups (—H) may be substituted with an alkyl group having 1 to 2 carbon atoms. More preferably, the hydrogen silxane copolymer of Chemical Formula 2 may be an alkylhydrosiloxane-dialkylsiloxane copolymer, and more preferably a methylhydrosiloxane-dimethylsiloxane copolymer, in which the R₁₂ is hydrogen and the remaining R₉ to R₁₁ and R₁₃ to R₁₉ may be substituted with methyl. The weight average molecular weight (Mw) of the hydrogen silaxane copolymer of Chemical Formula 2 may be 1000 to 10,000, and more preferably 1,500 to 4,000.

In addition, the Si—H content of the hydrogen siloxane copolymer of Chemical Formula 2 or derivative thereof may be 4 to 16 mmol/g, 4 to 10 mmol/g, or 4 to 5 mmol/g. When the Si—H content is less than the above range, the hydrogen siloxane copolymer may not be sufficiently crosslinked with the vinyl group included in the organopolysiloxane of Chemical Formula 1 or derivative thereof, and thus the dielectric loss may be increased. On the contrary, when the Si—H content exceeds the above range, unreacted Si—H groups may be generated to migrate to the surface of the adhesive layer.

The silicone-based compound preferably uses platinum as a catalyst in the reaction between the compound of Chemical Formula 1 and the compound of Chemical Formula 2. In addition, in the present disclosure, an addition reaction (curing) step may be particularly applied in order to increase the crosslinking density and decrease the dielectric constant.

A molar ratio of vinyl groups included in the organopolysiloxane of Chemical Formula 1 or derivative thereof to Si—H groups of the hydrogen siloxane copolymer of Chemical Formula 2 or derivative thereof may be 1:1 to 3.

When the molar ratio exceeds the above range, the crosslinking density increases, but an out-gassing phenomenon occurs due to hydrogen gas generated when Si—H that has not reacted with vinyl increases. On the contrary, when the molar ratio is less than the above range, a crosslinking point with vinyl decreases, and thus the crosslinking density and the dielectric constant are decreased, and the dielectric loss is increased, so that it may be difficult to react with the electrostatic chuck.

The adhesive layer 230 may be a pressure-sensitive adhesive layer. In addition to the organopolysiloxane of Chemical Formula 1 or derivative thereof and the hydrogen siloxane copolymer of Chemical Formula 2 or derivative thereof, an additional component may be included to improve the physical properties of the pressure-sensitive adhesive layer.

The additional component may include silicone gum, MQ resin, or the like. The adhesive layer may adhere to a sensitive portion such as a wafer or an organic coating layer, and has good adhesive strength and maintains a predetermined crosslinking density to maintain the adhesive properties of a product even after a certain period of time.

In addition, the adhesive layer 230 may be slot-die-coated or comma-coated on the conductive layer 220.

In addition, the adhesive layer 230 may be dried with hot air at 60 to 150° C. or 30 to 35 Hz for 90 to 180 seconds. When the drying time or the drying temperature is less than the above range, drying is insufficient, and thus curing or volatilization of the solvent is not completely performed, so that electrical properties such as dielectric constant may be affected.

In the system 1 for fixing the semiconductor wafer to the electrostatic chuck according to an embodiment of the present disclosure, the adhesive layer 230 of the semiconductor adhesive film 200 may adhere to a coating layer 310 formed on the semiconductor wafer 300.

In the system 1 for fixing the semiconductor wafer to the electrostatic chuck according to an embodiment of the present disclosure, the coating layer 310 may be formed of an organic coating agent.

In the system 1 for fixing the semiconductor wafer to the electrostatic chuck according to an embodiment of the present disclosure, the adhesive layer 230 may adhere to the semiconductor wafer 300 on which the coating layer 310 is formed. The coating layer 310 formed on the semiconductor wafer 300 may be formed to protect the semiconductor wafer 300. The coating layer 310 may be formed through methods, such as spin coating, chemical vapor deposition, physical vapor deposition, atomic layer deposition, and the like, and is not limited to the above methods. A material of the coating layer 310 may be formed of an organic coating agent, and more specifically, a material such as polyvinylpyrrolidone (PVP), polymethyl methacrylate (PMMA), or isopropyl alcohol (IPA) may be applied. A characteristic required by the adhesive layer 230 is to maintain the adhesive force to be separable from the coating layer 310 without damage to the wafer 300 even while the adhesive force with the coating layer 310 is sufficient, and another characteristic is formed to be separable from the coating layer 310 without residues that may be generated by a reaction between the coating layer 310 and the adhesive layer 230.

In the system 1 for fixing the semiconductor wafer 1 to the electrostatic chuck 100 according to an embodiment of the present disclosure, the semiconductor wafer 300 may be fixed to the electrostatic chuck 100 when a voltage is applied to the electrostatic chuck 100, and the semiconductor wafer 300 may be separated from the electrostatic chuck when no voltage is applied to the electrostatic chuck 100.

More specifically, when the voltage is applied to the electrostatic chuck 100, Coulomb force, Johnson-Rahbek force, or the like is generated between the electrostatic chuck 100 and the semiconductor wafer 300, so that the semiconductor wafer 300 may be fixed to the electrostatic chuck 100. At this time, the semiconductor adhesive film 200 may also react with the electrostatic chuck 100 to be fixed to the electrostatic chuck 100 by Coulomb force, Johnson-Rahmek force, or the like. The semiconductor adhesive film 200 may serve to stably fix the semiconductor wafer 300 to the electrostatic chuck 100, and serve to protect the semiconductor wafer 300 from being damaged by charges applied from the electrostatic chuck 100.

When no voltage is applied to the electrostatic chuck 100, a force generated between the semiconductor wafer 300 and the electrostatic chuck 100 disappears, so that the semiconductor wafer 300 may be separated from the electrostatic chuck 100. To this end, the force generated between the semiconductor adhesive film 200 and the electrostatic chuck 100 should also disappear, and to this end, when no voltage is applied to the electrostatic chuck 100, the remaining charges in the semiconductor adhesive film 200 should be formed to be extremely small.

In the system 1 for fixing the semiconductor wafer to the electrostatic chuck according to an embodiment of the present disclosure, the semiconductor adhesive film 200 may include a release film layer 240 formed on the adhesive layer 230, and the semiconductor wafer 300 may adhere to the adhesive layer 230 after the release film layer 240 is peeled from the adhesive layer 230.

The release film layer 240 may be formed on the semiconductor adhesive film 200 used in the system 1 for fixing the semiconductor wafer to the electrostatic chuck according to an embodiment of the present disclosure. When the release film layer 240 is not formed, the film 200 may be used in the form of a tape. The release film layer 240 may serve to protect the adhesive layer 230. The release film layer 240 may be removed after the semiconductor adhesive film 200 is fixed to the electrostatic chuck 100.

In the system 1 for fixing the semiconductor wafer to the electrostatic chuck according to an embodiment of the present disclosure, while the semiconductor adhesive film 200 is fixed to the electrostatic chuck 100 before the release film layer 240 is removed, when a voltage is applied to the electrostatic chuck 100, a force by which the electrostatic chuck 100 horizontally fixes the semiconductor adhesive film 200 may be formed to be 200 gf/150 mm or higher, and when no voltage is applied to the electrostatic chuck 100, the force by which the electrostatic chuck 100 horizontally fixes the semiconductor adhesive film 200 may be formed to be 1 gf/150 mm or less.

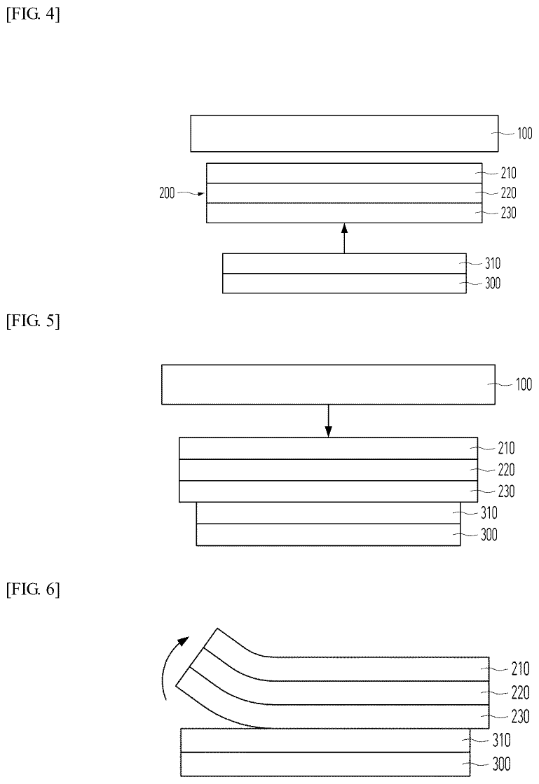

Referring to FIG. 2, the semiconductor adhesive film 200 may be fixed to the electrostatic chuck 100. At this time, when the voltage is applied to the electrostatic chuck 100 and the semiconductor adhesive film 200 reacts with the electrostatic chuck 100 to be fixed to the electrostatic chuck 200, it is necessary to fix the semiconductor wafer 300 so as not to move in the horizontal direction of the electrostatic chuck 100 and the horizontal direction of the semiconductor adhesive film 200. Since small shaking of the semiconductor wafer 300 is not required in a semiconductor process, it is also very important to be fixed in the horizontal direction. At this time, the force by which the electrostatic chuck 100 fixes the semiconductor adhesive film 200 in the horizontal direction may be formed to be 200 gf/150 mm or more, so that the electrostatic chuck 100 stably fixes the semiconductor adhesive film 200, and also stably fixes the wafer 300 adhering to the film 200.

When no voltage is applied to the electrostatic chuck 100, it is necessary to stably separate the wafer 300 from the electrostatic chuck 100, and a separation direction is formed in a horizontal direction of the electrostatic chuck 100 and a horizontal direction of the semiconductor adhesive film 200. Accordingly, when no voltage is applied to the electrostatic chuck 100, the force by which the electrostatic chuck 100 horizontally fixes the semiconductor adhesive film 200 may be formed to 1 gf/150 mm or less. The reason why there is a possibility that a force acts between the semiconductor adhesive film 200 and the electrostatic chuck 100 even when no voltage of the electrostatic chuck 100 is applied is that the residual charges may remain in the conductive layer 220 of the semiconductor adhesive film 200. Therefore, the conductive layer 220 is formed between the base layer 210 and the adhesive layer 230, and the conductive layer 220 has a thickness of 0.03 to 3 μm, so as to minimize attraction with the electrostatic chuck 100 generated by the residual charges formed in the conductive layer 220 when no voltage is applied to the electrostatic chuck 100. When the thickness of the conductive layer 220 exceeds 3 μm, the attraction between the semiconductor adhesive film 200 and the electrostatic chuck 100 is large due to the increased charges remaining in the conductive layer 220 even after the voltage of the electrostatic chuck 100 is turned off, and thus separation of the film 200 may not be smooth. In addition, when the thickness of the conductive layer 220 is smaller than 0.03 μm, the charge amount of the conductive layer 220 when the voltage is applied to the electrostatic chuck 100 is small, and thus the attraction generated between the film 200 and the electrostatic chuck 100 is too small, so that the fixing force may be weakened, and the conductive layer 220 may not block the application of the charges to the wafer 300.

In the system 1 for fixing the semiconductor wafer to the electrostatic chuck according to an embodiment of the present disclosure, the magnitude of the force for peeling the release film layer 240 from the adhesive layer 230 in the semiconductor adhesive film 200 may be 0.8 to 1.1 gf/25 mm.

The semiconductor adhesive film 200 may be supplied into semiconductor equipment through a roller system, so that the release film layer 240 of the semiconductor adhesive film 200 should not be peeled in the roller system. Therefore, the force for peeling the release film layer 24 from the adhesive layer 230 is preferably formed to be 0.8 gf/25 mm or more.

In addition, in the case where the force for peeling the release film layer 240 from the adhesive layer 230 is formed to a predetermined force or higher, as illustrated in FIG. 3, the semiconductor adhesive film 200 may be moved without being fixed to the electrostatic chuck 100 by the horizontal force applied to the semiconductor adhesive film 200 by the force for peeling the release film layer 240. Therefore, the force for peeling the release film layer 240 from the adhesive layer 230 is preferably formed to be 1.1 gf/25 mm or less.

In the system 1 for fixing the semiconductor wafer to the electrostatic chuck according to an embodiment of the present disclosure, the adhesive force formed between the coating layer 310 and the adhesive layer 230 may be formed to be 0.8 gf/25 mm or more and less than 2.5 gf/25 mm.

The reason for setting the upper limit of the adhesive force between the coating layer 310 and the adhesive layer 230 is to eliminate a possibility of damage to the wafer 300 that may occur when the coating layer 310 is peeled off from the wafer 300 when separating the coating layer 310 and the adhesive layer 230 from each other as illustrated in FIG. 6. Since the force by which the coating layer 310 adheres to the wafer 300 may be formed to be 2.5 gf/25 mm or more, the adhesive force between the coating layer 310 and the adhesive layer 230 may be formed to less than 2.5 gf/25 mm, so that the coating layer 310 may not be peeled off from the wafer 300 when separating the coating layer 310 and the adhesive layer 230 from each other.

The reason why the lower limit of the adhesive force between the coating layer 310 and the adhesive layer 230 is set is that when the adhesive force is lower than a reference value, there is a high possibility that a lifting phenomenon, a tunneling phenomenon (a phenomenon in which air enters a lifting portion), or the like occurs between the coating layer 310 and the adhesive layer 230. Therefore, the adhesive force between the coating layer 310 and the adhesive layer 230 may be formed to be 0.8 gf/25 mm or more.

In the system 1 for fixing the semiconductor wafer to the electrostatic chuck according to an embodiment of the present disclosure, the adhesive force formed between the coating layer 310 and the adhesive layer 230 may be maintained even at 10° C. to 110° C.

In the semiconductor manufacturing process, a film exhibiting normal performance even at various temperatures is required, and the system 1 for fixing the semiconductor wafer to the electrostatic chuck according to an embodiment of the present disclosure may operate normally even at 10° C. to 110° C., and more preferably, maintains the adhesive force formed between the coating layer 310 and the adhesive layer 230 so as to operate normally even at 25° C. to 100° C.

In the system 1 for fixing the semiconductor wafer to the electrostatic chuck according to an embodiment of the present disclosure, a Young's modulus value of the semiconductor adhesive film 200 while the release film layer 240 is removed may be formed to be 3500 to 4300 N/mm².

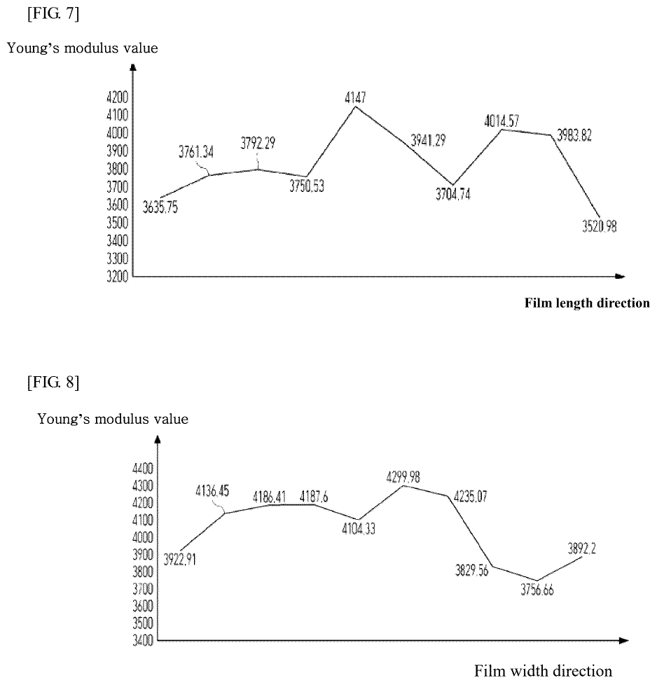

FIGS. 7 and 8 illustrate Young's modulus values measured in a longitudinal direction and a width direction of the semiconductor adhesive film 200 used in the system 1 for fixing the semiconductor wafer to the electrostatic chuck according to an embodiment of the present disclosure. When the Young's modulus value of the semiconductor adhesive film 200 is formed to be less than 3500 N/mm² while the release film layer 240 is removed, the fixing force to the wafer 300 may be weakened without a bending calibration force to the semiconductor wafer 300. When the semiconductor adhesive film 200 and the wafer 300 are peeled from each other when the Young's modulus value of the semiconductor adhesive film 200 exceeds 4300 N/mm², a peeling force is applied to the wafer 300, and thus cracks of the wafer 300 may occur.

FIGS. 2 to 6 illustrate a method for fixing a semiconductor wafer to an electrostatic chuck according to an embodiment of the present disclosure in sequence.

The method for fixing the semiconductor wafer to the electrostatic chuck according to an embodiment of the present disclosure is a method for fixing a semiconductor wafer 300 to an electrostatic chuck 100 by using a semiconductor adhesive film 200 in which a base layer 210, a conductive layer 220, an adhesive layer 230, and a release film layer 240 are laminated in sequence. The method may include a semiconductor adhesive film fixing step of fixing the semiconductor adhesive film 200 to the electrostatic chuck 100 so that the base layer 210 faces the electrostatic chuck 100 after a voltage is applied to the electrostatic chuck 100; a release film layer peeling step of peeling the release film layer 240 from the adhesive layer 230 of the semiconductor adhesive film 200; and a semiconductor wafer adhering step of adhering the semiconductor wafer 300 to the adhesive layer 230.

Referring to FIG. 2, the semiconductor adhesive film fixing step is a step of fixing the semiconductor adhesive film 200 to the electrostatic chuck 100. Since the conductive layer 220 of the semiconductor adhesive film 200 is formed between the base layer 210 and the adhesive layer 230, when a voltage is applied to the electrostatic chuck 100, charges are guided to the conductive layer 220, and thus the attraction is generated between the film 200 and the electrostatic chuck 100.

Referring to FIG. 3, the release film layer peeling step is a step of peeling the release film layer 240 from the film 200 fixed to the electrostatic chuck 100. The adhesive force between the adhesive layer 230 and the release film layer 240 is set in consideration of a possibility that the release film layer 240 may be peeled from a roller that supplies the semiconductor adhesive film 200 to semiconductor equipment and a possibility of moving the film 200 that may occur when the release film layer 240 is peeled from the film 200 fixed to the electrostatic chuck 100.

Referring to FIG. 4, the semiconductor wafer adhering step is a step of adhering the wafer 300 to the adhesive layer 230.

The method for fixing the semiconductor wafer to the electrostatic chuck according to an embodiment of the present disclosure may include an electrostatic chuck separating step of separating the semiconductor wafer 300 and the semiconductor adhesive film 200 together from the electrostatic chuck 100 after the applied voltage on the electrostatic chuck 100 is turned off, and a semiconductor wafer peeling step of separating the semiconductor wafer 300 from the adhesive layer 230.

Referring to FIG. 5, the electrostatic chuck separating step is a step of separating the wafer 300 and the film 200 while adhering to each other from the electrostatic chuck 100 after the applied voltage in the electrostatic chuck 100 is turned off. At this time, even while the applied voltage of the electrostatic chuck 100 is turned off, the attraction continues to operate between the electrostatic chuck 100 and the film 200 as the charges induced in the conductive layer 220 remain, so that the wafer 300 and the film 200 may not be separated from the electrostatic chuck 100. Therefore, the conductive layer 220 is formed between the base layer 210 and the adhesive layer 230, thereby minimizing the attraction between the film 200 and the electrostatic chuck 100 generated by the residual charges formed on the conductive layer 220.

Referring to FIG. 6, the semiconductor wafer peeling step is a step of separating the semiconductor wafer 300 from the adhesive layer 230. At this time, the adhesive force of the adhesive layer 230 may be set so as to fix the wafer 300 with an appropriate adhesive force without damaging the semiconductor wafer 300.

In the method for fixing the semiconductor wafer to the electrostatic chuck according to an embodiment of the present disclosure, in the semiconductor wafer adhering step, the coating layer 310 formed on the semiconductor wafer 300 and the adhesive layer 230 may adhere to each other.

As illustrated in FIG. 4, the adhesive layer 230 and the coating layer 310 formed on the semiconductor wafer 300 may adhere to each other.

In the method for fixing the semiconductor wafer to the electrostatic chuck according to an embodiment of the present disclosure, in the semiconductor wafer peeling step, the coating layer 310 and the adhesive layer 230 may be separated from each other.

As illustrated in FIG. 6, the semiconductor wafer peeling step is a step of separating the coating layer 310 from the adhesive layer 230. The adhesive force between the coating layer 310 and the adhesive layer 230 may be appropriately formed, so that the wafer 300 is not damaged when the coating layer 310 is separated from the adhesive layer 230 while stably maintaining the fixing force between the coating layer 310 and the adhesive layer 230.

In the method for fixing the semiconductor wafer to the electrostatic chuck according to an embodiment of the present disclosure, in the semiconductor adhesive film fixing step, a force by which the electrostatic chuck 100 horizontally fixes the semiconductor adhesive film 200 when a voltage is applied to the electrostatic chuck 100 may be formed to 200 gf/150 mm or more.

In FIG. 2, when the film 200 is moved in the horizontal direction, the release film layer 240 may not be stably peeled, and the wafer 300 may not accurately adhere to the film 200. Accordingly, when the voltage is applied to the electrostatic chuck 100, the force by which the electrostatic chuck 100 horizontally fixes the semiconductor adhesive film 200 may be formed to 200 gf/150 mm or more.

In the method for fixing the semiconductor wafer to the electrostatic chuck according to an embodiment of the present disclosure, in the electrostatic chuck separating step, a force by which the electrostatic chuck 100 horizontally fixes the semiconductor adhesive film 200 when no voltage is applied to the electrostatic chuck 100 may be formed to be 1 gf/150 mm or less.

Referring to FIG. 5, it is necessary to stably separate the film 200 and the wafer 300 from the electrostatic chuck 100 when no voltage is applied to the electrostatic chuck 100. The film 200 and the wafer 300 may be separated from the electrostatic chuck 100 by moving horizontally while separating. Therefore, when no voltage is supplied to the electrostatic chuck 100, a force by which the film 200 is horizontally fixed in the electrostatic chuck 100 may be formed to be 1 gf/150 mm or less.

In the method for fixing the semiconductor wafer to the electrostatic chuck according to an embodiment of the present disclosure, in the release film layer peeling step, the magnitude of the force of peeling the release film layer 240 from the adhesive layer 230 in the semiconductor adhesive film 200 may be formed to be 0.8 to 1.1 gf/25 mm.

FIG. 3 illustrates the release film layer peeling step, and the description of the magnitude of the peeling force generated between the adhesive layer 230 and the release film layer 240 is replaced with the description in the system 1.

In the method for fixing the semiconductor wafer to the electrostatic chuck according to an embodiment of the present disclosure, in the semiconductor wafer peeling step, the adhesive force formed between the coating layer 310 and the adhesive layer 230 may be 0.8 to 2.5 gf/25 mm.

In the method for fixing the semiconductor wafer to the electrostatic chuck according to an embodiment of the present disclosure, in the semiconductor wafer peeling step, the adhesive force formed between the coating layer and the adhesive layer may be maintained even at 10° C. to 110° C.

FIG. 6 illustrates the semiconductor wafer peeling step, and the description of the adhesive force generated between the coating layer 310 and the adhesive layer 230 and the description of the temperature are replaced with the description in the system 1.

In the method for fixing the semiconductor wafer to the electrostatic chuck according to an embodiment of the present disclosure, a Young's modulus value of the semiconductor adhesive film 200 after the release film layer peeling step may be formed to be 3500 to 4300 N/mm².

FIG. 3 illustrates the release film layer peeling step, and the description of the Young's modulus value of the semiconductor adhesive film 200 while the release film layer 240 is removed after the release film layer peeling step is replaced with the description in the system 1.

Hereinafter, Examples of the present disclosure will be described.

### EXAMPLE

### Preparation Example of Semiconductor Adhesive Film 200: Base Layer+Conductive Layer+Adhesive Layer+Release Film Layer

The semiconductor adhesive film 200 was formed so that the base layer 210, the conductive layer 220, the adhesive layer 230, and the release film layer 240 were laminated in sequence.

A reaction product was obtained by crosslinking 0.8 wt % of an aqueous solution of a mixture of poly(3,4-ethylenedioxythiophene) polystyrenesulfonate (PEDOT-PSS) and water-dispersed polyurethane (PEDOT-PSS:polyurethane=1:9 wt) with different concentrations (0 wt %, 0.05 wt %, 0.09 wt %, 0.1 wt %, 0.3 wt %, 0.5 wt %, and 0.6 wt %) of aziridine at normal temperature and normal pressure for 45 minutes. Then, the reaction product was gravure-coated on a 25 to 100 μm-thick polyethylene terephthalate base layer, and dried with 35 Hz hot air at 60° C. for 20 sec, 80° C. for 20 sec, and 100° C. for 20 sec to form a 0.03 to 3 μm-thick conductive layer.

27 g of polydimethylsiloxane (weight average molecular weight of about 650,000) of Chemical Formula 1 containing a vinyl group content of 0.2 mmol/g at both ends and 3 g of a methylhydrosiloxane-dimethylsiloxene copolymer (weight average molecular weight of about 2,500) of Chemical Formula 2 having an Si—H content of 4 mmol/g were mixed in 70 g of toluene, added with 0.005 g of platinum thereto as a catalyst and then reacted at normal temperature and normal pressure for 200 minutes to obtain a product. Then, the product was slot-die-coated on the conductive layer, and dried with 35 Hz hot air at 60° C. for 50 sec, 110° C. for 50 sec, and 150° C. for 50 sec to form an adhesive layer having a thickness of 15 to 50 μm.

### Test Example 1: Characteristics by Configuration of Semiconductor Adhesive Film

According to the presence or absence of the conductive layer 220 of the semiconductor adhesive film 200, the laminating order of the conductive layer 220, the components of the adhesive layer 230, and the like, a horizontal fixing force in the electrostatic chuck 100, a peeling force of the release film layer 240, and the like were determined.

Comparative Example 1: A semiconductor adhesive film in Comparative Example 1 was formed in the order of a base layer, an adhesive layer, and a release film layer, the base layer was formed of a polyolefin-based compound, and the adhesive layer was formed of an acrylic-based compound.

Comparative Example 2: A semiconductor adhesive film in Comparative Example 2 was formed in the order of a conductive layer, a base layer, a conductive layer, an adhesive layer, and a release film layer, a plurality of conductive layers was formed in the same manner as in Preparation Example of the semiconductor adhesive film 200, the base layer was formed of polyethylene terephthalate, and the adhesive layer was formed of a silicone-based compound according to Preparation Example of the semiconductor adhesive film 200.

Comparative Example 3: A semiconductor adhesive film in Comparative Example 3 was formed in the order of a base layer, a conductive layer, an adhesive layer, a release film layer, and a conductive layer, the conductive layer was formed in the same manner as in Preparation Example of the semiconductor adhesive film 200, the base layer was formed of polyethylene terephthalate, and the adhesive layer was formed of a silicone-based compound according to Preparation Example of the semiconductor adhesive film 200.

Example 1: A semiconductor adhesive film in Example 1 was formed as in Preparation Example of the semiconductor adhesive film 200.

TABLE 1

| | Com. | Com. | Com. | |
|---|---|---|---|---|
| Film Properties (Units) | Ex. 1 | Ex. 2 | Ex. 3 | Ex. 1 |
| Horizontal fixing force (gf/150 mm) | 0 | 1230 | 210 | 210 |
| of film when applied voltage is | | | | |
| provided | | | | |
| Horizontal fixing force (gf/150 mm) | 0 | 10~15 | 0 | 0 |
| of film without applied voltage | | | | |
| Release film peeling force (gf/25 | 8.8 | 0.8~1.1 | 0.6~0.9 | 0.9~1.1 |
| mm) | | | | |
| Presence or absence of residues | ◯ | X | X | X |
| when peeling coating layer and | | | | |
| adhesive layer | | | | |

### Description of Horizontal Fixing Force (Gf/150 mm) of Film

When a voltage was applied to the electrostatic chuck 100, the fixing force of the semiconductor adhesive film 200 in a horizontal direction was measured.

In Comparative Example 1, since the conductive layer was not formed, a horizontal fixing force with respect to the film in the electrostatic chuck 100 was not generated even when the voltage was applied. It was natural that since there was no conductive layer, the horizontal fixing force was not generated even when no voltage was applied.

In Comparative Example 2, the conductive layer was not only formed between the base layer and the adhesive layer, but also formed on the base layer. Therefore, the charge induction to the conductive layer was strongly formed when the voltage was applied to the electrostatic chuck 100. However, since the conductive layer was formed on the base layer and was exposed toward the electrostatic chuck 100, residual charges remained in the conductive layer even when the voltage was not applied, and thus an unnecessary fixing force exceeding 0.1 gf/150 mm was generated. Therefore, in Comparative Example 2, it was not possible to stably separate the film and the wafer even while the voltage of the electrostatic chuck was turned off.

In Comparative Example 3, the conductive layer was not only formed between the base layer and the adhesive layer, but also formed on the release film layer. Since the electrostatic chuck 100 was not formed close to the conductive layer in Comparative Example 3, a suitable horizontal fixing force of 210 gf/150 mm was generated even while the voltage was applied to the electrostatic chuck 100, and a suitable horizontal fixing force of 0 gf/150 mm was formed even while the voltage was not applied to the electrostatic chuck 100.

In Example 1, since the conductive layer was formed between the base layer and the adhesive layer, a suitable horizontal fixing force of 210 gf/150 mm was generated as the horizontal fixing force of the semiconductor adhesive film 200 in the electrostatic chuck 100 when the voltage was applied to the electrostatic chuck 100, and a suitable horizontal fixing force of 0 gf/150 mm was formed even while the voltage was not applied to the electrostatic chuck 100.

### Description of Release Film Peeling Force (Gf/25 mm)

The peeling force generated when the release film is peeled from the adhesive layer will be described.

The adhesive layer of Comparative Example 1 was formed of an acrylic-based compound, and in this case, the release film peeling force exceeded 2.5 gf/25 mm, which caused a problem that the film 200 could not be horizontally fixed in the electrostatic chuck 100 and then shaken or vibrated.

The adhesive layer in Comparative Example 3 was formed of a silicone-based compound, and the conductive layer was formed on the release film layer. A conductive layer having an additional thickness was formed on the releasing film layer, the physical properties of the conductive layer made it easier to peel the release film layer from the adhesive layer, and the peeling force was formed to be 0.6 to 0.9 gf/25 mm. Accordingly, there was a possibility that the peeling force between the adhesive layer and the release film layer in Comparative Example 3 may be less than 0.8 gf/25 mm, and in this case, there was a high risk that the release film layer would be peeled from a roller that provides the film to semiconductor equipment.

In Example 1 and Comparative Example 2, the adhesive layer was formed of a silicone-based compound, and the conductive layer was not formed on the release film layer. Therefore, the release film layer peeling force in Example 1 was formed to be 0.9 to 1.1 gf/25 mm, and the release film layer peeling force in Comparative Example 2 was formed to be 0.8 to 1.1 gf/25 mm, so that the release film peeling force may be formed to be between 0.8 and 1.1 gf/25 mm.

Description of Occurrence of Residues when Peeling Coating Layer and Adhesive Layer

In Comparative Example 1, the adhesive layer was formed of an acrylic-based compound, and when the adhesive layer adhered to and separated from the coating layer, there was a problem in that the coating layer was peeled off to leave residues.

On the other hand, in Comparative Examples 2 and 3 and Example 1, since the adhesive layer was formed of a silicone-based compound, there was a low possibility to cause a problem that the coating layer was peeled off and residues remained when the adhesive layer adhered to and separated from the coating layer.

### Test Example 2: Characteristics According to Adhesive Layer Material

Depending on the adhesive force between the coating layer and the adhesive layer, it was tested whether the coating layer was peeled off from the wafer or whether there were residues generated by a reaction between the coating layer and the adhesive layer. In addition, it was tested both in the case of separating the coating layer from the adhesive layer at initial adhesion and in the case of separating the coating layer and the adhesive layer after a predetermined period of time. Here, a material of the coating layer may be formed of an organic coating agent, and more specifically, a material such as polyvinylpyrrolidone (PVP), polymethyl methacrylate (PMMA), or isopropyl alcohol (IPA) may be applied.

Example 2: A semiconductor adhesive film in Example 2 was formed as in Preparation Example of the semiconductor adhesive film 200. The adhesive layer was formed of a silicone-based compound.

Comparative Example 4: An adhesive layer of a semiconductor adhesive film in Comparative Example 4 was formed of a urethane-based compound.

Comparative Example 5: An adhesive layer of a semiconductor adhesive film in Comparative Example 5 was formed of an acrylic-based compound.

TABLE 2

| | | Example | Comparative | Comparative |
|---|---|---|---|---|
| Classification | | 2 | Example 4 | Example 5 |
| Peeling of initial | Adhesive force (gf/25 mm) | 0.9 | 1.8 | 1.4 |
| adhesion | Presence of residues | X | X | Δ (stain |
| | | | | transfer) |
| | Peeling-off of coating layer | X | X | X |
| Peeling after 5 days | Adhesive force (gf/25 mm) | 0.9 | 2.1 | 4.2 |
| | Presence of residue | X | Δ (stain | ◯ (occurrence |
| | | | transfer) | of transition) |
| | Peeling-off of coating layer | X | X | Peeling-off |
| Peeling after 7 days | Adhesive force (gf/25 mm) | 1.1 | 3.4 | 8.8 |
| | Presence of residue | X | Δ (stain | ◯ (occurrence |
| | | | transfer) | of transition) |
| | Peeling-off of coating layer | X | X | ◯ (peeling-off) |

In Table 2, peeling of initial adhesion meant peeling 30 minutes after the coating layer and the adhesive layer adhered to each other.

The adhesive force between the semiconductor wafer 300 and the coating layer 310 was 2.5 gf/25 mm. Accordingly, when the adhesive force between the coating layer 310 and the adhesive layer 230 was formed to be 2.5 gf/25 mm or more, there was a high possibility that the coating layer may be peeled off. In addition, strong adhesion between the coating layer 310 and the adhesive layer 230 may increase a possibility that the coating layer 310 and the adhesive layer 230 may react with each other to leave residues.

In the case of Example 2, the adhesive layer was formed of a silicone-based compound, and an initial adhesive force at which the coating layer 310 and the adhesive layer 230 were adhered was formed to be 0.9 gf/25 mm. There was no significant difference in the adhesive force (0.9 gf/25 mm) after 5 days from the adhesion between the coating layer 310 and the adhesive layer 230 and the adhesive force (1.1 gf/25 mm) after 7 days compared with the initial adhesive force. In addition, the adhesive force after 7 days was higher than the initial adhesive force, but did not exceed 2.5 gf/25 mm. This shows the superiority when the adhesive layer was formed of a silicone-based compound. In addition, in the case of Example 2, problems such as generation of residues and coating film peeling-off did not occur in all cases of peeling of initial adhesion, peeling after 5 days, peeling after 7 days, and the like.

In the case of Comparative Example 4, it can be seen that the initial adhesive force at which the coating layer and the adhesive layer were adhered was 1.8 gf/25 mm, whereas the adhesive force after 7 days was 3.4 gf/25 mm, which was nearly twice the initial adhesive force, and thus there was a problem of the adhesive layer formed of the urethane-based compound used in Comparative Example 4. In addition, in Comparative Example 4, a problem of generation of residues or peeling-off of the coating film did not occur in the peeling of initial adhesion, but in the case of peeling after 5 days and peeling after 7 days, it can be observed that there was a problem that stains caused due to residues generated by a reaction between the coating layer and the adhesive layer remained on the wafer.

In the case of Comparative Example 5, it can be seen that the initial adhesive force at which the coating layer and the adhesive layer were adhered was 1.4 gf/25 mm, whereas the adhesive force after 7 days was 8.8 gf/25 mm, which was nearly seven times the initial adhesive force, and thus there was a problem of the adhesive layer formed of the acrylic-based compound used in Comparative Example 5. In addition, it can be also seen that in Comparative Example 5, even in the peeling of initial adhesion, stains due to residues generated by the reaction between the coating layer and the adhesive layer remained on the wafer, and in the peeling after 5 days and the peeling after 7 days, a problem of peeling-off the coating film occurred.

### Test Example 3: Characteristics According to Adhesive Force Between Adhesive Layer and Coating Layer

Even in the case where the adhesive layer was formed of the silicone-based compound, when the adhesive force between the adhesive layer and the coating layer exceeded 2.5 gf/25 mm, generation of residues or peeling-off of the coating layer may occur when peeling the adhesive layer and the coating layer.

Here, a material of the coating layer may be formed of an organic coating agent, and more specifically, a material such as polyvinylpyrrolidone (PVP), polymethyl methacrylate (PMMA), or isopropyl alcohol (IPA) may be applied.

TABLE 3

| | | | Comparative | Comparative | Comparative |
|---|---|---|---|---|---|
| Classification | | Example 3 | Example 6 | Example 7 | Example 8 |
| Adhesive layer material | | Silicone-based | Silicone-based | Silicone-based | Silicone-based |
| | | compound | compound | compound | compound |
| Adhesive force (gf/25 mm) | | 1.5 | 2.5 | 3.3 | 7.0 |
| Peeling of initial | Presence of residue | X | X | X | ◯ (occurrence |
| adhesion | | | | | of transition) |
| | Peeling-off of coating layer | X | X | X | X |
| Peeling after 2 | Presence of residue | X | Δ (stain | ◯ (occurrence | ◯ (occurrence |
| weeks | | | transfer) | of transition) | of transition) |
| | Peeling-off of coating layer | X | X | X | ◯ (peeling-off) |

In Table 3, peeling of initial adhesion meant peeling 30 minutes after the coating layer and the adhesive layer adhered to each other.

From Example 3, it can be seen that the adhesive force between the adhesive layer 230 formed of a silicone-based compound and the coating layer 240 was formed to be 1.5 gf/25 mm, and in this case, there was no problem that residues remained or the coating layer was peeled off both in the case where the adhesive layer and the coating layer were peeled off at the initial adhesion and in the case where the adhesive layer and the coating layer were peeled off after two weeks.

In Comparative Example 6, it can be seen that the adhesive force between the adhesive layer formed of the silicone-based compound and the coating layer was 2.5 gf/25 mm, and in this case, when the adhesive layer and the coating layer were peeled off at the initial adhesion, there was no problem in that residues remained or the coating layer was peeled off. However, when the adhesive layer and the coating layer were peeled off after 2 weeks from the adhesion, there was a case in which stains due to residues caused by a reaction between the coating layer and the adhesive layer remained on the wafer. In Comparative Example 6, the adhesive force was 2.5 gf/25 mm, and thus a residue problem or a coating layer peeling-off problem hardly occurred, but in the case of peeling after two weeks, there was a problem in that very fine residue stains remained.

In Comparative Example 7, it can be seen that the adhesive force between the adhesive layer formed of the silicone-based compound and the coating layer was 3.3 gf/25 mm, and in this case, when the adhesive layer and the coating layer were peeled at the initial adhesion, there was no problem in that residues remained or the coating layer was peeled off. However, when the adhesive layer and the coating layer were peeled off after 2 weeks from the adhesion, there was a problem that residues caused by a reaction between the adhesive layer and the coating layer remained on the wafer.

In Comparative Example 8, it can be seen that the adhesive force between the adhesive layer formed of the silicone-based compound and the coating layer was 7.0 gf/25 mm, and in this case, there was a problem that residues caused by a reaction between the adhesive layer and the coating layer remained on the wafer. In addition, in the case of peeling two weeks after the adhesive layer adhered to the coating layer, there was a problem that the coating layer was peeled off.

### Test Example 4: Characteristics According to Temperature

In Examples 4 to 7, bonding with the adhesive layer of the semiconductor adhesive film of the semiconductor wafer 300 was performed at different temperatures. At this time, the semiconductor adhesive films used in Examples 4 to 7 were formed according to Preparation Examples of the semiconductor adhesive films described above.

TABLE 4

| Classification | | Example 4 | Example 5 | Example 6 | Example 7 |
|---|---|---|---|---|---|
| Bonding temperature | | Normal | 50° C. | 75° C. | 100° C. |
| | | temperature | | | |
| | | (25° C.) | | | |
| Peeling of initial | Adhesive force (gf/25 mm) | 1.2 | 0.9 | 0.8 | 1.1 |
| adhesion | Presence of residue | X | X | X | X |
| | Peeling-off of coating layer | X | X | X | X |
| Peeling after 14 | Adhesive force (gf/25 mm) | 1.2 | 0.8 | 1.0 | 1.2 |
| days | Presence of residue | X | X | X | X |
| | Peeling-off of coating layer | X | X | X | X |

From Examples 4 to 7, it can be seen that regardless of the temperature in the range of 25° C. to 100° C., the adhesive force between the adhesive layer and the coating layer of the film prepared according to Preparation Example of the semiconductor adhesive film was maintained at 0.8 gf/25 mm or more and less than 2.5 gf/25 mm. In addition, regardless of the temperatures in the range of 25° C. to 100° C., there was no problem that residues were generated or the coating layer was peeled off. Therefore, the semiconductor adhesive film 200 according to an embodiment of the present disclosure could have the same physical properties even under various temperature conditions.

While the present disclosure has been particularly described with reference to detailed embodiments thereof, the embodiments specifically describe the present disclosure, but the present disclosure is not limited thereto, and it will be apparent that modification and improvement of the present disclosure can be made by those skilled in the art within the technical spirit of the present disclosure.

Simple modification and change of the present disclosure all belong to the scope of the present disclosure and a detailed protection scope of the present disclosure will be clear by the appended claims.

### EXPLANATION OF REFERENCE NUMERALS AND SYMBOLS

1: System for fixing semiconductor wafer to electrostatic chuck
100: Electrostatic chuck
200: Semiconductor adhesive film
210: Base layer
220: Conductive layer
230: Adhesive layer
240: Release film layer
300: Wafer
310: Coating layer

1. A system for fixing a semiconductor wafer to an electrostatic chuck, the system comprising:
an electrostatic chuck;
a semiconductor adhesive film including a base layer, a conductive layer formed on the base layer, and an adhesive layer formed on the conductive layer, in which the semiconductor adhesive film is fixed to the electrostatic chuck so as to face the electrostatic chuck; and
a semiconductor wafer adhering to the adhesive layer.

2. The system of claim 1, wherein the adhesive layer of the semiconductor adhesive film adheres to the coating layer formed on the semiconductor wafer, or
wherein the semiconductor wafer is fixed to the electrostatic chuck when a voltage is applied to the electrostatic chuck, and the semiconductor wafer is separated from the electrostatic chuck when no voltage is applied to the electrostatic chuck.

3. (canceled)

4. The system of claim 1, wherein the semiconductor adhesive film includes a release film layer formed on the adhesive layer, and
the semiconductor wafer adheres to the adhesive layer after the release film layer is peeled from the adhesive layer.

5. The system of claim 4, wherein while the semiconductor adhesive film is fixed to the electrostatic chuck before the release film layer is removed,
a force by which the electrostatic chuck horizontally fixes the semiconductor adhesive film is formed to be 200 gf/150 mm or more when a voltage is applied to the electrostatic chuck, and the force by which the electrostatic chuck horizontally fixes the semiconductor adhesive film is formed to be 1 gf/150 mm or less when no voltage is applied to the electrostatic chuck.

6. The system of claim 4, wherein a magnitude of a force of peeling the release film layer from the adhesive layer in the semiconductor adhesive film is formed to be 0.8 to 1.1 gf/25 mm.

7. The system of claim 2, wherein an adhesive force formed between the coating layer and the adhesive layer is formed to be 0.8 gf/25 mm or more and less than 2.5 gf/25 mm.

8. The system of claim 7, wherein the adhesive force formed between the coating layer and the adhesive layer is maintained even at 10° C. to 110° C.

9. The system of claim 1, wherein the semiconductor adhesive film has a Young's modulus value of 3500 to 4300 N/mm².

10. The system of claim 2, wherein the adhesive layer includes a silicon-based compound, or wherein the coating layer is formed of an organic coating agent.

11. (canceled)

12. A method for fixing a semiconductor wafer to an electrostatic chuck by using a semiconductor adhesive film in which a base layer, a conductive layer, an adhesive layer, and a release film layer are laminated in sequence, the method comprising:
a semiconductor adhesive film fixing step of fixing the semiconductor adhesive film to the electrostatic chuck so that the base layer faces the electrostatic chuck after a voltage is applied to the electrostatic chuck;
a release film layer peeling step of peeling the release film layer from the adhesive layer of the semiconductor adhesive film; and
a semiconductor wafer adhering step of adhering the semiconductor wafer to the adhesive layer.

13. The method of claim 12, comprising:
an electrostatic chuck separating step of separating the semiconductor wafer and the semiconductor adhesive film together from the electrostatic chuck after the applied voltage to the electrostatic chuck is turned off; and
a semiconductor wafer peeling step of separating the semiconductor wafer from the adhesive layer.

14. The method of claim 12, wherein in the semiconductor wafer adhering step,
the coating layer formed on the semiconductor wafer and the adhesive layer adhere to each other.

15. The method of claim 14, wherein in the semiconductor wafer peeling step,
the coating layer and the adhesive layer are separated from each other.

16. The method of claim 12, wherein in the semiconductor adhesive film fixing step, a force by which the electrostatic chuck horizontally fixes the semiconductor adhesive film when a voltage is applied to the electrostatic chuck is formed to be 200 gf/150 mm or more.

17. The method of claim 13, wherein in the electrostatic chuck separating step, a force by which the electrostatic chuck horizontally fixes the semiconductor adhesive film when no voltage is applied to the electrostatic chuck is formed to be 1 gf/150 mm or less.

18. The method of claim 12, wherein in the semiconductor wafer peeling step, a magnitude of a force of peeling the release film layer from the adhesive layer in the semiconductor adhesive film is formed to be 0.8 to 1.1 gf/25 mm.

19. The method of claim 15, wherein in the semiconductor wafer peeling step, an adhesive force formed between the coating layer and the adhesive layer is formed to be 0.8 gf/25 mm or more and less than 2.5 gf/25 mm.

20. The method of claim 19, wherein in the semiconductor wafer peeling step, the adhesive force formed between the coating layer and the adhesive layer is maintained even at 10° C. to 110° C.

21. The method of claim 12, wherein after the release film layer peeling step, the semiconductor adhesive film has a Young's modulus value of 3500 to 4300 N/mm².

22. The method of claim 14, wherein the adhesive layer includes a silicon-based compound, or wherein the coating layer is formed of an organic coating agent.

23. (canceled)
